(19) United States
(12) Patent Application Publication
(10) Pub. No.: US 2025/0107115 A1
(43) Pub. Date: Mar. 27, 2025

(54) Power Semiconductor Device and Method of Producing a Power Semiconductor Device

(71) Applicant: Infineon Technologies AG, Neubiberg (DE)

(72) Inventors: Manfred Pfaffenlehner, München (DE); Arnab Biswas, München (DE); Maria Cotorogea, München (DE); Hans-Joachim Schulze, Taufkirchen (DE); Philipp Seng, München (DE)

(21) Appl. No.: 18/826,506

(22) Filed: Sep. 6, 2024

(30) Foreign Application Priority Data
Sep. 26, 2023 (DE) 102023209400.2

(51) Int. Cl. H01L 29/861; H01L 27/06

(52) U.S. Cl. CPC H10D 8/00; H10D 1/474; H10D 84/403

(57) ABSTRACT

A power semiconductor diode includes: a semiconductor body with a drift region of a first conductivity type; a first load terminal at a first side of the semiconductor body coupled to an anode region of a second conductivity type in the semiconductor body and coupled to the drift region; a second load terminal at a second side of the semiconductor body coupled to both cathode regions of the first conductivity type and short regions of the second conductivity type of a doped region in the semiconductor body and coupled to the drift region; and a resistive element external of the semiconductor body. The diode conducts a load current between the load terminals, a first path of which crosses the anode region, drift region and cathode regions and a second path of which crosses the anode region, drift region and short regions. The resistive element exhibits a resistance having a positive-temperature-coefficient.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

Irrespective of whether or not the device exhibits an RC configuration, it is generally an aim to design a power semiconductor device such it exhibits a high robustness, i.e., in terms of handling overload situations during which the load current temporarily exceeds the nominal load current, e.g., due to a short circuit situation or the like.

To this end, it is generally aimed to provide the device with a more homogenous temperature distribution. It has been observed that a lateral inhomogeneous temperature distribution during operation (self-heating) can result in a reduced switching ruggedness behavior and/or of the power cycling stability. An inhomogeneous temperature dependence can also reduce the short circuit ruggedness of a transistor and the surge current ruggedness of a diode. Such negative effect is amplified in the presence of solder voids. Furthermore, regarding a SiC based MOSFET, an inhomogeneous temperature distribution can amplify the bipolar degradation.

### SUMMARY

According to an embodiment, a power semiconductor diode comprises: a semiconductor body with a drift region of a first conductivity type; a first load terminal at a first side of the semiconductor body and coupled to an anode region of a second conductivity type, the anode region being arranged in the semiconductor body and coupled to the drift region; a second load terminal at a second side of the semiconductor body and coupled to both cathode regions of the first conductivity type and short regions of the second conductivity type of a doped region, the doped region being arranged in the semiconductor body and coupled to the drift region, whereby the drift region may optionally contain a buffer layer of the first conductivity type. The power semiconductor diode is configured to conduct a load current between the first load terminal and the second load terminal. A first path of the load current crosses each of anode region, the drift region and the cathode regions. A second path of the load current crosses each of the anode region, the drift region and the short regions. At least one resistive element is arranged external of the semiconductor body within the second load current path, wherein the at least one resistive element exhibits a resistance having a non-linear positive-temperature-coefficient.

According to another embodiment, a power semiconductor diode, comprises: a semiconductor body with a drift region of a first conductivity type, whereby the drift region may optionally contain a buffer layer of the first conductivity type; a first stack with a first load terminal at a first side of the semiconductor body and coupled to an anode region of a second conductivity type, the anode region being arranged in the semiconductor body and above the drift region; a second stack at a second side of the semiconductor body, wherein the second stack comprises a second load terminal and at least one resistive element arranged external of the semiconductor body, wherein the power semiconductor diode is configured to conduct a load current between the first load terminal and the second load terminal; a doped region within the semiconductor body and below the drift region, the doped region comprising cathode regions of the first conductivity type and short regions of the second conductivity type in contact to the second stack. The at least one resistive element exhibits a resistance having a positive-temperature-coefficient greater than that of the second load terminal. At least one of the short regions is coupled to the second load terminal via the at least one resistive element.

In accordance with a further embodiment, a power semiconductor circuit comprises a power semiconductor diode as described above and a power semiconductor transistor, wherein the power semiconductor diode is connected anti-parallel to the power semiconductor transistor to form a freewheeling diode.

In a yet further embodiment, a power semiconductor device comprises, in an active region surrounded by an edge termination region: a semiconductor body with a drift region of a first conductivity type, whereby the drift region may optionally contain a buffer layer of the first conductivity type; a first load terminal at a first side of the semiconductor body and coupled to a body region of a second conductivity type, the body region being arranged in the semiconductor body and coupled to the drift region; a second load terminal at a second side of the semiconductor body and coupled to a doped region, the doped region being arranged in the semiconductor body and coupled to the drift region. The power semiconductor device is configured to conduct a load current between the first load terminal and the second load terminal, wherein a path of the load current crosses each of the body region, the drift region and the doped region. At least one resistive element is arranged external of the semiconductor body within the load current path, wherein the at least one resistive element exhibits a resistance having a positive-temperature-coefficient greater than the second load terminal.

According to a further embodiment, a method of producing a power semiconductor diode comprises forming the following components: a semiconductor body with a drift region of a first conductivity type, whereby the drift region may optionally contain a buffer layer of the first conductivity type; a first load terminal at a first side of the semiconductor body and coupled to an anode region of a second conductivity type, the anode region being arranged in the semiconductor body and coupled to the drift region; a second load terminal at a second side of the semiconductor body and coupled to both cathode regions of the first conductivity type and short regions of the second conductivity type of a doped region, the doped region being arranged in the semiconductor body and coupled to the drift region. The power semiconductor diode is configured to conduct a load current between the first load terminal and the second load terminal. A first path of the load current crosses each of anode region, the drift region and the cathode regions. A second path of the load current crosses each of the anode region, the drift region and the short regions. At least one resistive element is arranged external of the semiconductor body within the second load current path, wherein the at least one resistive element exhibits a resistance having a positive-temperature-coefficient.

According to a further embodiment, a method of producing a power semiconductor diode comprises forming the following components: a semiconductor body with a drift region of a first conductivity type, whereby the drift region may optionally contain a buffer layer of the first conductivity type; a first stack with a first load terminal at a first side of the semiconductor body and coupled to an anode region of a second conductivity type, the anode region being arranged in the semiconductor body and above the drift region; a second stack at a second side of the semiconductor body, wherein the second stack comprises a second load terminal and at least one resistive element arranged external of the semiconductor body, wherein the power semiconductor diode is configured to conduct a load current between the first load terminal and the second load terminal; a doped region within the semiconductor body and below the drift region, the doped region comprising cathode regions of the first conductivity type and short regions of the second conductivity type in contact to the second stack. The at least one resistive element exhibits a resistance having a positive-temperature-coefficient greater than that of the second load terminal. At least one of the short regions is coupled to the second load terminal via the at least one resistive element.

According to a further embodiment, a method of producing a power semiconductor device comprises forming, in an active region surrounded by an edge termination region, the following components: a semiconductor body with a drift region of a first conductivity type, whereby the drift region may optionally contain a buffer layer of the first conductivity type; a first load terminal at a first side of the semiconductor body and coupled to a body region of a second conductivity type, the body region being arranged in the semiconductor body and coupled to the drift region; a second load terminal at a second side of the semiconductor body and coupled to a doped region, the doped region being arranged in the semiconductor body and coupled to the drift region. The power semiconductor device is configured to conduct a load current between the first load terminal and the second load terminal, wherein a path of the load current crosses each of the body region, the drift region and the doped region. At least one resistive element is arranged external of the semiconductor body within the load current path, wherein the at least one resistive element exhibits a resistance having a positive-temperature-coefficient greater than the second load terminal.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a vertical cross-section of a power semiconductor device in accordance with an example;

FIGS. 2 and 3 both schematically and exemplarily illustrate a section of a vertical cross-section of a respective power semiconductor device in accordance in accordance with one or more embodiments;

FIGS. 4 and 5 both schematically and exemplarily illustrate a section of a vertical cross-section of a respective power semiconductor diode in accordance in accordance with one or more embodiments; and

FIG. 6 schematically and exemplarily illustrates a power semiconductor circuit in accordance with some embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

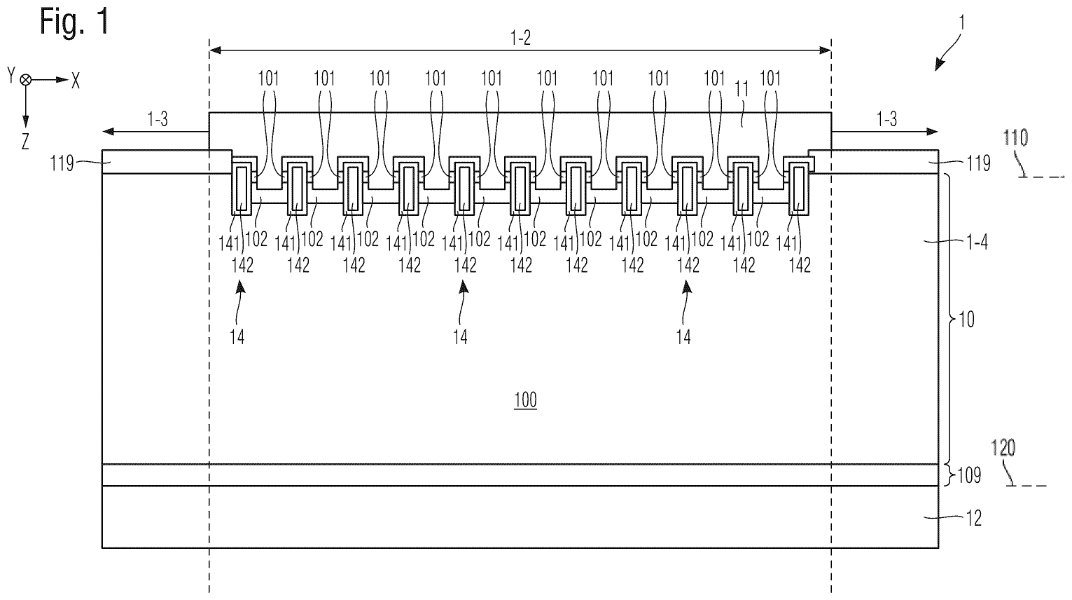

FIG. 1 schematically and exemplarily illustrates a section of a vertical cross-section of a power semiconductor device 1 in accordance with one or more embodiments. The power semiconductor device 1, herein also referred to as “device”, comprises, in a single chip, a semiconductor body 10 configured to conduct a load current between a first load terminal 11 at a first side 110 of the semiconductor body 10 and a second load terminal 12 at a second side 120 of the semiconductor body 10.

The first side 110 and the second side 120 may be arranged opposite of each other. E.g., the first side 110 is a front side of the device 1 and the second side 120 is a back side of the device 1. Accordingly, the device 1 may exhibit a vertical configuration according to which the load current within the device 1 follows a path in parallel to the vertical direction Z.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 and its doping level influence the voltage blocking capabilities of the device 1.

The device 1 further comprises trenches 14 extending from the first side 110 towards the second side 120, e.g., along the vertical direction Z. Each trench 14 includes a trench electrode 141 separated from the semiconductor body 10 by a trench insulator 142.

Said trenches 14 can be control trenches, wherein each trench electrode 141 of is electrically insulated from the first load terminal 11 and configured to receive a control signal. To this end, each trench electrode 141 can be electrically connected to a (non-illustrated) control terminal of the device 1, in accordance with an embodiment. Herein, the trenches 14 are also referred to as “control trenches” and the corresponding trench electrodes 141 as “control trench electrodes”.

The control trenches 14 laterally confine mesa portions of the semiconductor body 10. E.g., each mesa portion is electrically connected to the first load terminal 11, e.g., by means of a respective contact plug extending from the first load terminal 11 into the semiconductor body 10, as illustrated. Alternatively, a planar contact may be employed. Each mesa portion may be configured for load current conduction. For example, each mesa portion comprises a semiconductor body region 102 of the second conductivity type electrically connected to the first load terminal 11 and, optionally, a semiconductor source region 101 of the first conductivity type electrically connected to the first load terminal 11, wherein the semiconductor source region 101 is isolated from the drift region 100 by at least the semiconductor body region 102. The adjacent control trench electrode 141 may be configured to induce, upon being subject with a corresponding ON-control signal, an inversion channel in the semiconductor body region 102. This process may set the device 1 into the forward conducting state. The adjacent control trench electrode 141 may be configured to cut off, upon being subject with a corresponding OFF-control signal, said inversion channel in the semiconductor body region 102, which can set the device 1 into the forward blocking state.

The above-described features of the power semiconductor device 1 may allow designing diverse trench-mesa-patterns at the first side 110. Such pattern may include further trench types and/or further mesa types, e.g., source trenches whose trench electrodes are electrically connected to the first load terminal 11, floating trenches whose trench electrodes are not connected with a defined electrical potential, or second type control trenches whose trench electrodes are connected to a different control terminal as compared to the control trench electrodes 141 to implement a dual or multi gate configuration and so on. Also, other type mesa portions may be implemented, e.g., those having a different threshold voltage, dummy mesa portions and so on.

A doped region 109 of the semiconductor body 10 below the drift region 100 adjoining the second load terminal 12 at the second side 120 can be configured in accordance with the designated characteristic of the device 1. E.g., the doped region 109 can be an emitter region of the second conductivity type, if the device 1 shall exhibit an IGBT configuration. The emitter region is arranged in contact with the second load terminal 12. In addition, a field stop region (not illustrated) of the first conductivity type can be provided between the drift region 100 and the second load terminal 12, wherein the field stop region exhibits a greater dopant concentration than the drift region 100. If the device 1 shall exhibit a MOSFET configuration, the emitter region is omitted such that the field stop region (or another highly doped region of the first conductivity type) would adjoin the second load terminal 12. If the device 1 shall exhibit an RC IGBT configuration, the emitter region may exhibit subsections of the first conductivity type, as it is known to the skilled person.

The above-described components of the power semiconductor device 1 are arranged in the active region 1-2 of the device 1, which is surrounded by an edge termination region 1-3. In the active region 1-2, the trenches 14 and the associated mesa portions may form a cell field, which may exhibit a cellular/needle cell configuration or a stripe cell configuration. The edge termination region 1-3 is typically not employed for load current conduction, as it is known to the skilled person. The edge termination region 1-3 is terminated by the chip edge 1-4.

The path of the load current between the first load terminal 11 and the second load terminal 12 crosses each of the body region 102, the drift region 100 and the doped region 109.

The temperature distribution within the device 1 depends on the distribution of the load current. In following, a feature is proposed that allows designing the device 1 with a beneficial temperature distribution, in particular for high ambient temperature.

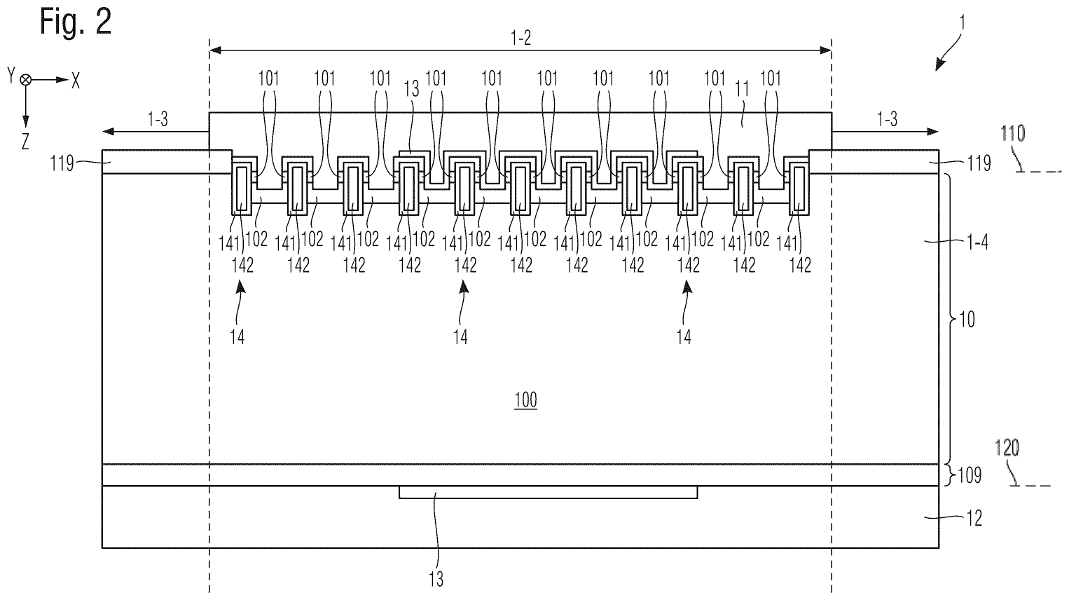

Referring to FIG. 2, which illustrates a similar structure as FIG. 1, it is proposed to include, within the load current path but external of the semiconductor body, a resistive element 13 that exhibits a resistance having a positive-temperature-coefficient, e.g., greater than a positive-temperature-coefficient of the second load terminal 12. For example, the resistance of the resistive element 13 exhibits a positive-temperature-coefficient at least 2 times larger or even at least 10 times larger than the positive-temperature-coefficient of the second load terminal 12.

As illustrated in FIG. 2, the resistive element 13 can be provided both at the first side 110 (e.g., a front side) and at the second side 120 (e.g., a back side). In other embodiments, the resistive element 13 is provided either at the first side 110 or at the second side.

In an embodiment, the at least one resistive element 13 is arranged, with respect to a lateral extension of the active region 1-2, in the central portion of the active region 1-2. E.g., due to the resistance of the at least one resistive element 13, this may cause the load current concentration to decrease in the central portion of the active region 1-2 and to increase in the peripheral portion of the active region 1-2 (closer to the edge termination region 1-3) in case of high ambient/operating temperatures. Thus, a more beneficial temperature distribution within the semiconductor body 10 may be achieved.

The exact dimensioning and positioning of the at least one resistive element 13 can be adapted to the configuration of the cell field within the active region 1-2. For example, the at least one resistive element 13 exhibits a total lateral cross-sectional area amounting to at least 20% of the total lateral cross-sectional area of the active region 1-2.

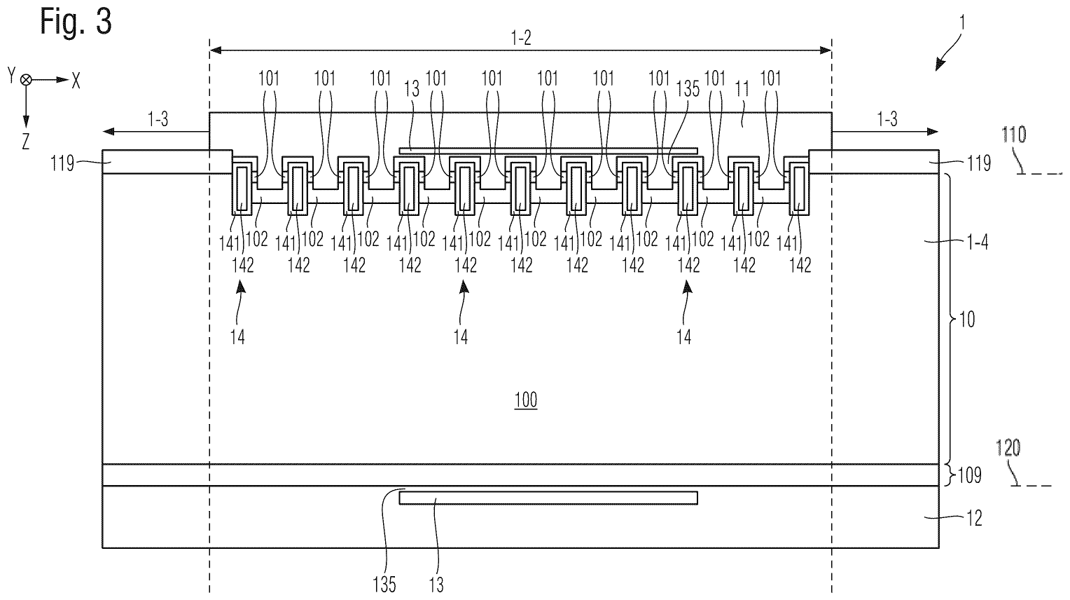

Furthermore, the at least one resistive element 13 may be arranged in contact with the semiconductor body 10, as illustrated in FIG. 2, thereby forming an interface layer between the semiconductor body 10 and at least one of the first load terminal 11 and the second load terminal 12. Alternatively, as illustrated in FIG. 3, the at least one restive element 13 is coupled with the semiconductor body 10 via an intermediate layer 135. E.g., the intermediate layer 135 comprises one or more of Al, AlSi, AlSiCu and Ti. Further, the intermediate layer 135 can exhibit a thickness along the vertical direction Z of at least 3 nm and of at most 3 μm.

The intermediate layer 135 may be a highly conductive layer, e.g., exhibit a lower resistance as the at least one resistive element 13.

In accordance with embodiments, the device 1 comprises, at the first side 110 of the semiconductor body 10, a first stack of different material layers that form, inter alia, the first load terminal and include, optionally, at least one of the at least one the resistive element 13. Furthermore, in accordance with embodiments, the device 1 comprises, at the second side 120 of the semiconductor body 10, a second stack of different material layers that form, inter alia, the second load terminal 12 and include, optionally, at least one of the at least one the resistive element 13. E.g., the first stack and the second stack are configured such that the device 1 can be installed within an application, e.g., such that the second stack may be mounted within a module and that a bond wire may be connected to the first stack.

The at least one element 13 can accordingly be integrated in the power semiconductor device 1 by being included in at least one of the first stack and the second stack.

As described above, the device 1 illustrated in FIG. 2 may exhibit a MOSFET or IGBT configuration. For example, its semiconductor body 10 is based on silicon or, alternatively, on a wide bandgap material, such as SiC or GaN.

In accordance with embodiments described herein, it is also proposed to equip a power semiconductor device having a diode configuration with such resistive element 13.

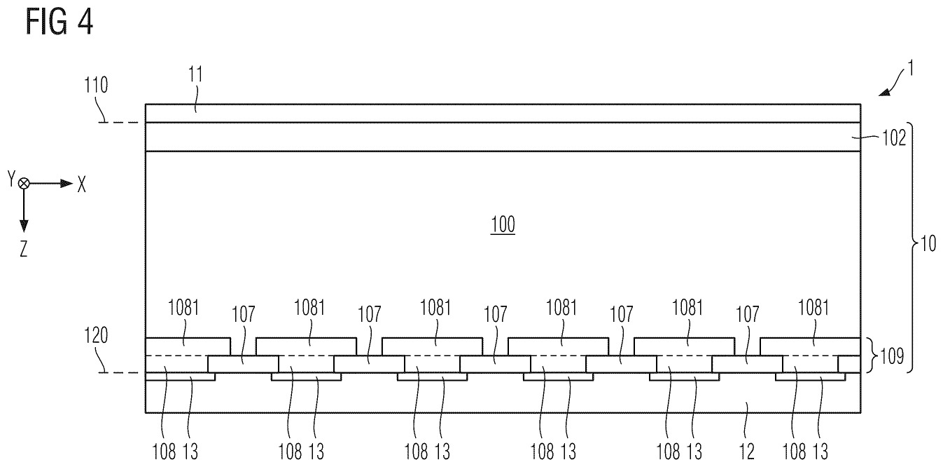

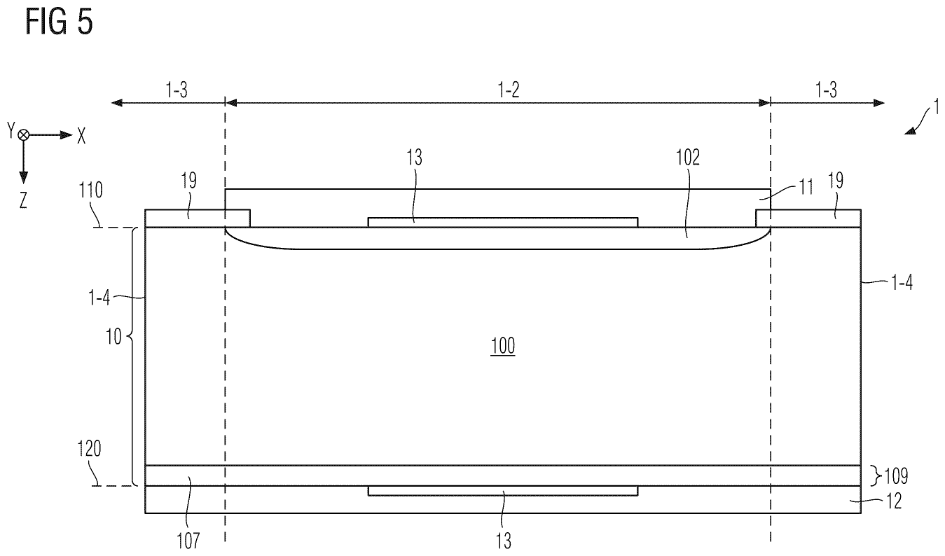

E.g., exemplary embodiments of such diode 1 or illustrated in FIGS. 4 and 5, to which it will now be referred to.

The power semiconductor device of FIG. 4 is configured like the power semiconductor device 1 of FIGS. 2 and 3. The power semiconductor device 1 of FIG. 4 has a diode configuration (instead of a transistor configuration) and will accordingly be referred to as diode 1. The diode 1 comprises: a semiconductor body 10 with a drift region 100 of a first conductivity type; a first load terminal 11 at a first side 110 of the semiconductor body 10 and coupled to an anode region 102 of a second conductivity type, the anode region 102 being arranged in the semiconductor body 10 and coupled to the drift region 100; a second load terminal 12 at a second side 120 of the semiconductor body 10 and coupled to both cathode regions 107 of the first conductivity type and short regions 108 of the second conductivity type of a doped region 109. The doped region 109 is arranged in the semiconductor body 10 and coupled to the drift region 100. The power semiconductor diode 1 is configured to conduct a load current between the first load terminal 11 and the second load terminal 12. A first path of the load current crosses each of anode region 102, the drift region 100 and the cathode regions 107. A second path of the load current crosses each of the anode region 102, the drift region 100 and the short regions 108. At least one resistive element 13 is arranged external of the semiconductor body 10 within the second load current path, wherein the at least one resistive element 13 exhibits a resistance having a positive-temperature-coefficient.

Here, it shall be noted that the term “load current” refers to all kind of load currents that occur within the semiconductor body 10, not only nominal forward load currents but also currents that occur during switching processes or other transient situations, like the change between the blocking state and the conducting state and associated currents and current paths. For example, in the short regions 108, a load current is only observed during a turn-off process.

For example, as described above, the first load terminal 11 is part of a first stack at the first side 110 of the semiconductor body 10 of the diode 1. The anode region 102 is arranged in the semiconductor body 10 and above the drift region 100, for example. A second stack at a second side 120 of the semiconductor body 10 may be provided, wherein the second stack comprises the second load terminal 12. For example, the second stack also comprises the at least one resistive element 13 arranged external of the semiconductor body 10. Furthermore, the doped region 109 within the semiconductor body 10 can be arranged below the drift region 100. As explained, the doped region 109 may comprise the cathode regions 107 of the first conductivity type and the short regions 108 of the second conductivity type, wherein both the cathode region 107 and the short regions 108 may be arranged in contact to the second stack.

The at least one resistive element may exhibit a resistance having a positive-temperature-coefficient greater than that of the second load terminal 12.

Furthermore, at least one of the short regions 108 is coupled to the second load terminal 12 via the at least one resistive element 13, in accordance with an embodiment.

In an embodiment, the at least one resistive element 13 is integrated with the power semiconductor diode 1, e.g., by forming a part of the first stack and/or the second stack.

For example, the at least one resistive element 13 is coupled to at least one of the short regions 108. It may also be provided that there is one resistive element for each short region 108. In an embodiment, the diode 1 comprises at least one resistive element 13 for each of at least 90% of the number of short regions 109. Or, several or all of the short regions 108 share the same resistive element 13.

As explained above with respect to FIGS. 2 and 3, the at least one resistive element may directly adjoin the semiconductor body 10 (i.e., be arranged in contact with a portion of the semiconductor body 10) or be coupled to it via said intermediate layer 135.

For example, the at least one resistive element 13 is arranged in contact with at least one of the short regions 108. Or, the at least one resistive element 13 is coupled to at least one of the short regions 108 via the intermediate layer 135. The intermediate layer 135 in the diode 1 may be configured as described above with respect to FIG. 3.

As illustrated in FIG. 4, the short regions 108 and the cathode regions 109 are arranged alternately next to each other along the first lateral direction X. Both the short regions 108 and the cathode regions 109 are arranged in contact with the second stack comprising the second load terminal and the at least one resistive element 13. The at least one resistive element 13 may be arranged so as to laterally overlap with at least one of the short regions 108, either entirely or at least partially.

In an embodiment, the doped region 109 further comprises deep regions 1081 of the second conductivity type arranged in contact and above the short regions 108, as illustrated in FIG. 4. These deep regions 1081 may exhibit a greater dopant concentration as the short regions 108.

Regarding all embodiments described herein, the semiconductor body 10 may of course comprise further and/or other doped regions as described and illustrated. For example, highly doped contact regions may be provided within the anode/body region 102. Also, there can be barrier regions and/or damage regions, depending on the configuration of the device.

Regarding all embodiments described herein, it may be provided, for example, that each of the at least one resistive element 13 has, within a low temperature range, a first resistance of less than twice of the resistance of the second load terminal 12 and, within a high temperature range, a second resistance amounting to at least 3 times or to at least 5 times or even to at least 10 times the first resistance. For example, the first temperature range comprises temperatures between −50° C. and 100° C., and the second temperature range comprises temperatures between 120° C. and 300° C. For example, the second temperature range comprises temperatures between 120° C. and 200° C. for a Si (silicon)-based power semiconductor device. For example, the second temperature range comprises temperatures between 200° C. and 300° C. for a SiC (silicon carbide)-based power semiconductor device. The first temperature may be oriented at a room temperature or a standard temperature. The second temperature may be oriented at or equal to a (maximum) specified operating temperature of the power semiconductor device.

Further, regarding all embodiments described herein, the at least one resistive element 13 is configured to reduce an injection of holes into the semiconductor body 10 at high operating temperatures, e.g., at operating temperatures within said second temperature range. E.g., thereby, lower switching losses at high temperatures may be achieved.

Still regarding all embodiments described herein, the at least one resistive element 13 may comprise at least one of doped barium-titanate, doped titanium, and platinum.

As described above, the device 1, irrespective of having a transistor configuration (cf. FIGS. 2 and 3) or a diode configuration (cf. FIGS. 4 and 5) is intended to for power applications (and not for data storage or computational/logical applications). E.g., the nominal load current of the device is at least 1 A and the blocking voltage at least 400 V.

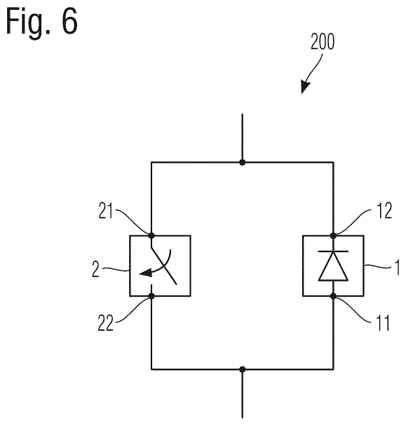

Regarding FIG. 6, in accordance with an embodiment, the diode 1 as exemplarily described above may be integrated into a power semiconductor circuit 200. Such circuit 200 may comprise a power semiconductor transistor 2, e.g., an IGBT, and the diode 1 may be connected anti-parallel to the transistor and act as a freewheeling diode. In particular in such application, it can be beneficial to equip the diode with the above described at least one resistive element 13, e.g., to avoid local overheating in the diode 1.

Presented herein is also a method of producing a power semiconductor device.

For example, according to a further embodiment, a method of producing a power semiconductor diode comprises forming the following components: a semiconductor body with a drift region of a first conductivity type; a first load terminal at a first side of the semiconductor body and coupled to an anode region of a second conductivity type, the anode region being arranged in the semiconductor body and coupled to the drift region; a second load terminal at a second side of the semiconductor body and coupled to both cathode regions of the first conductivity type and short regions of the second conductivity type of a doped region, the doped region being arranged in the semiconductor body and coupled to the drift region. The power semiconductor diode is configured to conduct a load current between the first load terminal and the second load terminal. A first path of the load current crosses each of anode region, the drift region and the cathode regions. A second path of the load current crosses each of the anode region, the drift region and the short regions. At least one resistive element is arranged external of the semiconductor body within the second load current path, wherein the at least one resistive element exhibits a resistance having a positive-temperature-coefficient.

According to a further embodiment, a method of producing a power semiconductor diode comprises forming the following components: a semiconductor body with a drift region of a first conductivity type; a first stack with a first load terminal at a first side of the semiconductor body and coupled to an anode region of a second conductivity type, the anode region being arranged in the semiconductor body and above the drift region; a second stack at a second side of the semiconductor body, wherein the second stack comprises a second load terminal and at least one resistive element arranged external of the semiconductor body, wherein the power semiconductor diode is configured to conduct a load current between the first load terminal and the second load terminal; a doped region within the semiconductor body and below the drift region, the doped region comprising cathode regions of the first conductivity type and short regions of the second conductivity type in contact to the second stack. The at least one resistive element exhibits a resistance having a positive-temperature-coefficient greater than that of the second load terminal. At least one of the short regions is coupled to the second load terminal via the at least one resistive element.

According to a further embodiment, a method of producing a power semiconductor device comprises forming, in an active region surrounded by an edge termination region, the following components: a semiconductor body with a drift region of a first conductivity type; a first load terminal at a first side of the semiconductor body and coupled to a body region of a second conductivity type, the body region being arranged in the semiconductor body and coupled to the drift region; a second load terminal at a second side of the semiconductor body and coupled to a doped region, the doped region being arranged in the semiconductor body and coupled to the drift region. The power semiconductor device is configured to conduct a load current between the first load terminal and the second load terminal, wherein a path of the load current crosses each of the body region, the drift region and the doped region. At least one resistive element is arranged external of the semiconductor body within the load current path, wherein the at least one resistive element exhibits a resistance having a positive-temperature-coefficient greater than the second load terminal.

Embodiments of the above-described methods correspond to the embodiments of the power semiconductor device/diode 1 described above. Accordingly, these embodiments of the method will not literally be described herein, but it is referred to the above.

E.g., regarding the embodiment illustrated in FIG. 4, in an exemplary method, before a deposition of the backside metallization to form the second load terminal 12, a “metal to insulator” material can be deposited on the wafer backside and structured with a lithography and etched, so that the restive elements 13 only remain on areas where the short regions 108 in the active region 1-2 are (e.g., with a certain overlap to the cathode regions 107 to cover for process variations. Afterwards, the backside metal can be deposited. In that way, the electric contact of the short regions 108 is temperature dependent so that the injection of holes from the short regions 108 at high temperatures will be reduced. Therefore, the turn-off losses can be significantly lowered at high temperatures and the softness will be optimized. At room temperature, the softness behaves like in the reference device without a “metal to insulator” material, but at higher temperatures the injection out of the p-shorts is reduced which leads to lower turn-off losses compared to the reference structure without a “metal to insulator” material (resistive elements 13). Furthermore, the risk that dynamic avalanche will occur at high temperatures will be reduced too, because the hole injection from the backside will be reduced. As described above, possible materials for forming the resistive elements 13 can be doped barium titanate, doped titanium or resistances based on platinum.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGalnN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor diode, comprising:
a semiconductor body with a drift region of a first conductivity type;
a first load terminal at a first side of the semiconductor body and coupled to an anode region of a second conductivity type, the anode region being arranged in the semiconductor body and coupled to the drift region;
a second load terminal at a second side of the semiconductor body and coupled to both cathode regions of the first conductivity type and short regions of the second conductivity type of a doped region, the doped region being arranged in the semiconductor body and coupled to the drift region; and
at least one resistive element arranged external of the semiconductor body,
wherein the power semiconductor diode is configured to conduct a load current between the first load terminal and the second load terminal,
wherein a first path of the load current crosses each of the anode region, the drift region and the cathode regions,
wherein a second path of the load current crosses each of the anode region, the drift region and the short regions,
wherein the at least one resistive element is within the second load current path and exhibits a resistance having a non-linear positive-temperature-coefficient.

2. The power semiconductor diode of claim 1, wherein the at least one resistive element is integrated with the power semiconductor diode.

3. The power semiconductor diode of claim 1, wherein the at least one resistive element is coupled to at least one of the short regions.

4. The power semiconductor diode of claim 1, wherein the at least one resistive element is arranged in contact with at least one of the short regions.

5. The power semiconductor diode of claim 1, wherein the at least one resistive element is coupled to at least one of the short regions via an intermediate layer.

6. The power semiconductor diode of claim 5, wherein the intermediate layer comprises Al, AlSi, AlSiCu, Ti and/or exhibits a thickness along a vertical direction of at least 3 nm and of at most 3 μm.

7. The power semiconductor diode of claim 1, wherein the at least one resistive element laterally overlaps with at least one of the short regions at least partially.

8. The power semiconductor diode of claim 1, wherein the short regions and the cathode regions are arranged alternately next to each other along a first lateral direction.

9. The power semiconductor diode of claim 1, wherein at least one resistive element is provided for each of at least 90% of the short regions.

10. The power semiconductor diode of claim 1, wherein each of the at least one resistive element has, within a low temperature range, a first resistance of less than twice of the resistance of the second load terminal and, within a high temperature range, a second resistance amounting to at least ten times the first resistance.

11. The power semiconductor diode of claim 1, wherein the doped region further comprises deep regions of the second conductivity type arranged in contact and above the short regions.

12. The power semiconductor diode of claim 1, wherein the at least one resistive element is configured to reduce an injection of holes into the semiconductor body at high operating temperatures.

13. The power semiconductor diode of claim 1, wherein the at least one resistive element comprises at least one of doped barium-titanate, doped titanium, and resistances based on platinum.

14. The power semiconductor diode of claim 1, wherein the power semiconductor diode is configured for a maximum blocking voltage of at least 400 V and/or a nominal load current of at least 1 A.

15. A power semiconductor circuit, comprising:
the power semiconductor diode of claim 1; and
a power semiconductor transistor,
wherein the power semiconductor diode is connected anti-parallel to the power semiconductor transistor to form a freewheeling diode.

16. A power semiconductor diode, comprising:
a semiconductor body with a drift region of a first conductivity type;
a first stack with a first load terminal at a first side of the semiconductor body and coupled to an anode region of a second conductivity type, the anode region being arranged in the semiconductor body and above the drift region;
a second stack at a second side of the semiconductor body, wherein the second stack comprises a second load terminal and at least one resistive element arranged external of the semiconductor body, wherein the power semiconductor diode is configured to conduct a load current between the first load terminal and the second load terminal; and
a doped region within the semiconductor body and below the drift region, the doped region comprising cathode regions of the first conductivity type and short regions of the second conductivity type in contact to the second stack,
wherein the at least one resistive element exhibits a resistance having a positive-temperature-coefficient greater than that of the second load terminal,
wherein at least one of the short regions is coupled to the second load terminal via the at least one resistive element.

17. The power semiconductor diode of claim 16, wherein the at least one resistive element is integrated with the power semiconductor diode.

18. The power semiconductor diode of claim 16, wherein the at least one resistive element is coupled to at least one of the short regions.

19. The power semiconductor diode of claim 16, wherein the at least one resistive element is arranged in contact with at least one of the short regions.

20. The power semiconductor diode of claim 16, wherein the at least one resistive element is coupled to at least one of the short regions via an intermediate layer.

21. The power semiconductor diode of claim 20, wherein the intermediate layer comprises Al, AlSi, AlSiCu, Ti and/or exhibits a thickness along a vertical direction of at least 3 nm and of at most 3 μm.

22. The power semiconductor diode of claim 16, wherein the at least one resistive element laterally overlaps with at least one of the short regions at least partially.

23. The power semiconductor diode of claim 16, wherein the short regions and the cathode regions are arranged alternately next to each other along a first lateral direction.

24. The power semiconductor diode of claim 16, wherein at least one resistive element is provided for each of at least 90% of the short regions.

25. The power semiconductor diode of claim 16, wherein each of the at least one resistive element has, within a low temperature range, a first resistance of less than twice of the resistance of the second load terminal and, within a high temperature range, a second resistance amounting to at least ten times the first resistance.

26. The power semiconductor diode of claim 16, wherein the doped region further comprises deep regions of the second conductivity type arranged in contact and above the short regions.

27. The power semiconductor diode of claim 16, wherein the at least one resistive element is configured to reduce an injection of holes into the semiconductor body at high operating temperatures.

28. The power semiconductor diode of claim 16, wherein the at least one resistive element comprises at least one of doped barium-titanate, doped titanium, and resistances based on platinum.

29. The power semiconductor diode of claim 16, wherein the power semiconductor diode is configured for a maximum blocking voltage of at least 400 V and/or a nominal load current of at least 1 A.

30. A power semiconductor circuit, comprising:
the power semiconductor diode of claim 16; and
a power semiconductor transistor,
wherein the power semiconductor diode is connected anti-parallel to the power semiconductor transistor to form a freewheeling diode.

31. A power semiconductor device, comprising, in an active region surrounded by an edge termination region:
a semiconductor body with a drift region of a first conductivity type;
a first load terminal at a first side of the semiconductor body and coupled to a body region of a second conductivity type, the body region being arranged in the semiconductor body and coupled to the drift region;
a second load terminal at a second side of the semiconductor body and coupled to a doped region, the doped region being arranged in the semiconductor body and coupled to the drift region; and
at least one resistive element arranged external of the semiconductor body,
wherein the power semiconductor device is configured to conduct a load current between the first load terminal and the second load terminal,
wherein a path of the load current crosses each of the body region, the drift region and the doped region,
wherein the at least one resistive element is within the load current path and exhibits a resistance having a positive-temperature-coefficient greater than the second load terminal.

32. The power semiconductor device of claim 31, wherein the at least one resistive element is arranged, with respect to a lateral extension of the active region, in a central portion of the active region.

33. The power semiconductor device of claim 31, wherein the at least one resistive element exhibits a total lateral cross-sectional area amounting to at least 20% of a total lateral cross-sectional area of the active region.

34. The power semiconductor device of claim 31, wherein the semiconductor body is based on a wide bandgap semiconductor material.
